(19) United States
(12) Patent Application Publication
(10) Pub. No.: US 2026/0309579 A1
(43) Pub. Date: Oct. 8, 2026

(54) PHOTODETECTOR INSPECTION APPARATUS AND PHOTODETECTOR INSPECTION METHOD

(71) Applicant: Mitsubishi Electric Corporation, Tokyo (JP)

(72) Inventors: Yohei MIKAMI, Tokyo (JP); Tetsuhiro FUKAO, Tokyo (JP)

(73) Assignee: Mitsubishi Electric Corporation, Tokyo (JP)

(21) Appl. No.: 19/484,339

(22) PCT Filed: Jul. 14, 2023
(86) PCT No.: PCT/JP2023/026102

§ 371 Date: Nov. 13, 2025

(51) Int. Cl. G01M 11/02; G01N 21/88; G01N 21/95

(52) U.S. Cl. CPC G01M 11/0214; G01N 21/8806; G01N 21/9501; G01N 2021/8848

(57) ABSTRACT

A photodetector inspection apparatus according to the present disclosure includes: a measurement stage comprising a region including a device placement portion for placing the back-incident type photodetector with the light receiving surface thereof in contact, the region being formed of a transparent member with respect to the laser light; anti-reflection films formed on the front surface of the device placement portion and on the front surface of a portion opposed to the device placement portion on the back surface side of the measurement stage, respectively; a light source unit capable of selecting either CW light or pulsed light; and an optical fiber unit connected at one end to the light source unit, wherein one end of the optical fiber unit is an oblique polished surface and a portion opposed to the device placement portion has a lens shape.

### TECHNICAL FIELD

The present disclosure relates to a photodetector inspection apparatus and a photodetector inspection method.

### BACKGROUND ART

As a photodetector inspection apparatus and a photodetector inspection method, for example, in the photodetector inspection apparatus described in Patent Document 1, in order to measure the light sensitivity of photodiodes, a semiconductor wafer on which a plurality of photodiodes are mounted is set in a wafer tester, then, laser light from a laser head is irradiated onto a single photodiode, and thus the light sensitivity value is calculated on the basis of the output voltage at that time.

In the photodetector inspection apparatus different from Patent Document 1, the inspection is carried out in a state where a back-incident type photodetector is flip-chip mounted on a sub-mount.

### CITATION LIST

### Patent Document

Patent Document 1: Japanese Laid-Open Patent Publication No. 2006-324588

### SUMMARY OF THE INVENTION

### Problem to be Solved by the Invention

The photodetector inspection apparatus described in Patent Document 1 measures semiconductor wafers individually, thereby failing to take into account the influence of the peripheral circuitry of the photodetector during measurement.

In the photodetector inspection method in which the back-incident type photodetector is inspected while the back-incident type photodetector is flip-chip mounted on the sub-mount, it is necessary to flip-chip mount the back-incident type photodetector in advance in order to measure device characteristics of the back-incident type photodetector. That is, there is a problem that device characteristics cannot be measured in a state of a bare back-incident type photodetector before flip-chip mounting.

The present disclosure has been made in order to solve such problems, and it is an object of the present disclosure to provide a photodetector inspection apparatus and a photodetector inspection method capable of accurately inspecting device characteristics of a bare back-incident type photodetector.

### Means to Solve the Problem

A photodetector inspection apparatus according to the present disclosure is a photodetector inspection apparatus for inspecting a back-incident type photodetector configured to receive laser light incident from the back surface side including: a measurement stage comprising at least a region including a device placement portion for placing the back-incident type photodetector, the region being formed of a transparent member with respect to the laser light; anti-reflection films that are configured to prevent reflection of the laser light, the anti-reflection films being formed on the front surface of the device placement portion and on the front surface of a portion opposed to the device placement portion on the back surface side of the measurement stage, respectively; a light source unit that is configured to emit the laser light and is capable of selecting either CW light or pulsed light from the laser light; and an optical fiber unit that is connected at one end to the light source unit and is configured to guide the laser light and to emit the laser light from the other end toward the portion opposed to the device placement portion.

A photodetector inspection method according to the present disclosure is a photodetector inspection method for inspecting a back-incident type photodetector that receives laser light incident from the back surface side, the method including: a step of placing the back-incident type photodetector on a device placement portion of a measurement stage formed of a material transparent to the laser light, the device placement portion being provided with anti-reflection films formed on the front surface side and on the back surface side, respectively and being configured to prevent reflection of the laser light; a step of emitting the laser light emitted from a light source unit through an optical fiber unit toward a portion opposed to the device placement portion on the back surface side of the measurement stage; and a step of measuring device characteristics of the back-incident type photodetector by contacting a probe with the front surface of the back-incident type photodetector.

### Effect of the Invention

In the photodetector inspection apparatus and the photodetector inspection method according to the present disclosure, it is possible to inspect the bare back-incident type photodetector, thereby it is not necessary to assemble the back-incident type photodetector before inspecting the device characteristics thereof, thus providing an effect of enabling inspection under the same conditions as the final product before incorporating back-incident type photodetectors into the final product.

### BRIEF DESCRIPTION OF THE DRAWINGS

FIG. 1 is an overview diagram showing a photodetector inspection apparatus according to Embodiment 1;

FIG. 2 is an overview diagram showing a photodetector inspection apparatus according to Embodiment 2;

FIG. 3 is an overview diagram showing a photodetector inspection apparatus according to Embodiment 3;

FIG. 4 is an overview diagram showing a photodetector inspection apparatus according to Embodiment 4;

FIG. 5 is an overview diagram showing a photodetector inspection apparatus according to Embodiment 5;

FIG. 6 is an overview diagram showing a photodetector inspection apparatus according to Embodiment 6;

FIG. 7 is a top view showing a measurement stage of the photodetector inspection apparatus according to Embodiment 6.

### DESCRIPTION OF EMBODIMENTS

### Embodiment 1

### Configuration of Photodetector Inspection Apparatus According to Embodiment 1

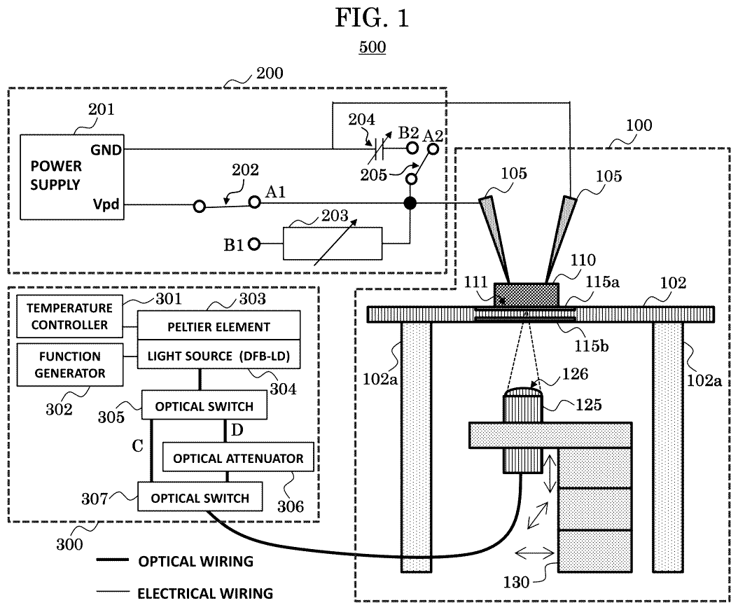

FIG. 1 is an overview diagram showing a photodetector inspection apparatus 500 according to Embodiment 1. The photodetector inspection apparatus 500 includes an inspection unit 100, a power supply unit 200, and a light source unit 300.

The photodetector inspection apparatus 500 is particularly suitable for measuring the back-incident type photodetector 110, but it is also capable of measuring photodetectors other than the back-incident type photodetector 110.

### Structure of Inspection Unit

The inspection unit 100 includes: a measurement stage 102; a plurality of measurement stage legs 102a that support the measurement stage 102; a probe 105 that contacts the back-incident type photodetector 110 to supply a measurement current; an optical fiber unit 125 that is provided on the back surface side of the measurement stage 102 and guides laser light emitted from the light source unit 300 and has a lens portion 126 whose tip is processed into a lens shape; and an XYZ stage 130 that moves the optical fiber unit 125 in a three-dimensional direction.

On the upper surface (hereinafter, the surface is referred to as front surface, and the surface opposed to the upper surface is referred to as back surface) of the measurement stage 102, at least a region including a portion (hereinafter, referred to as device placement portion 111) where the back-incident type photodetector 110 is placed when the back-incident type photodetector 110 is measured is formed of a transparent member (hereinafter, referred to as transparent member) with respect to the laser light emitted from the light source unit 300. The entire measurement stage 102 may be formed of the transparent member.

An anti-reflection film 115a is formed on the front surface of the device placement portion 111 of the measurement stage 102. An anti-reflection film 115b is formed on the front surface of a portion opposed to the device placement portion 111 on the back surface side of the measurement stage 102. The anti-reflection film 115a may be embedded in the transparent member constituting the measurement stage 102 such that the front surface of the measurement stage 102 coincides with the front surface of the anti-reflection film 115a. The anti-reflection film 115b may be embedded in the transparent member constituting the measurement stage 102 such that the back surface of the measurement stage 102 coincides with the front surface of the anti-reflection film 115b. The anti-reflection film 115a and the anti-reflection film 115b have a function of preventing reflection of the laser light.

The lens portion 126 formed at the tip of the optical fiber unit 125 is provided to focus the laser light guided within the optical fiber unit 125 onto the light receiving surface of the back-incident type photodetector 110 placed on the measurement stage 102. When focusing the laser light, the optical fiber unit 125 is moved in a three-dimensional direction by using the XYZ stage 130, thereby the focus of the lens portion 126 is adjusted so as to coincide with the light receiving surface (not shown) provided on the back surface side of the back-incident type photodetector 110.

In the photodetector inspection apparatus 500 according to Embodiment 1, the back-incident type photodetector 110 to be measured is placed on the device placement portion 111 provided so as to be substantially on the same plane as the measurement stage 102. Therefore, the laser light emitted from the lens portion 126 is incident on the back surface of the back-incident type photodetector 110 from the direction perpendicular to the front side, thereby causing a part of the laser light to be reflected by the back surface of the back-incident type photodetector 110, which may reduce the input of the laser light to the back-incident type photodetector 110 and/or cause multiple reflection of the laser light. Therefore, the reflection of the laser light by the back surface of the back-incident type photodetector 110 is prevented by forming the anti-reflection film 115a on the device placement portion 111 and the anti-reflection film 115b on the front surface of the portion opposed to the device placement portion 111 on the back surface side of the measurement stage 102.

### Configuration of Power Supply Unit

The power supply unit 200 includes: a power supply 201; a first electric switch 202 connected to the output terminal Vpd of the power supply 201; a variable resistor 203 arranged between the point B1 and the electrical wiring on the output side of the first electric switch 202; a variable-capacitance bypass capacitor 204 connected to the ground terminal GND of the power supply 201; and a second electric switch 205 arranged between the output terminal Vpd and the ground terminal GND. The output terminal Vpd and the ground terminal GND are respectively connected to the probe 105.

The first electrical switch 202 allows selection between a case where the variable resistor 203 is connected in series with the output terminal Vpd and a case where no such resistor is connected, by connecting to either the point A1 or the point B1. In addition, the second electrical switch 205 allows selection between a case where the variable-capacitance bypass capacitor 204 is connected in series with the ground terminal GND and a case where no such capacitor is connected, by connecting to either the point A2 or the point B2.

### Structure of Light Source Unit

The light source unit 300 includes: a light source 304 configured by DFB-LD and emitting laser light; a Peltier element 303 and a temperature controller 301 for controlling the temperature of the light source 304 to be constant; a function generator 302 for controlling the laser light emitted from the light source 304 so as to generate CW light or pulse light; an optical switch 305 connected to the light source 304 by optical wiring; an optical attenuator 306 connected to the optical switch 305; and an optical switch 307 for selecting the laser light from the optical switch 305 and the laser light from the optical attenuator 306.

The optical switch 305 selects either the path C or the path D to select that the laser light passes through optical attenuator 306 or not. The optical attenuator 306 monitors the power of the light output from the optical fiber unit 125 prior to measurement. In addition, the optical attenuator 306 allows the input laser light to be attenuated to the desired attenuation amount.

The laser light emitted from the light source unit 300 is input to the optical fiber unit 125 of the inspection unit 100 through the optical wiring.

### Photodetector Inspection Method According to Embodiment 1

The photodetector inspection method according to Embodiment 1 will be described below.

The back-incident type photodetector 110 to be measured is placed on the device placement portion 111 of the measurement stage 102. When placing, the back surface side of the back-incident type photodetector, that is, the side where the light receiving surface is provided, is placed on the device placement portion 111.

The temperature controller 301 drives the Peltier element 303 to control the DFB-LD as the light source 304 to a desired constant temperature.

When the path C is selected, the laser light emitted from the DFB-LD is emitted to the inspection unit 100 through the optical switch 305 and the optical switch 307. When the path D is selected, the laser light is emitted to the inspection unit 100 through the optical switch 305, the optical attenuator 306 and the optical switch 307.

The laser light guided to the optical fiber unit 125 is focused by the lens portion 126 formed at the tip of the optical fiber unit 125, and then focused on the light receiving surface provided on the back surface side of the back-incident type photodetector 110 placed on the device placement portion 111 of the measurement stage 102.

When focusing the laser light, the optical fiber unit 125 is moved in the three-dimensional direction by using the XYZ stage 130, so that the focus of the lens portion 126 is on the light receiving surface of the back-incident type photodetector 110 prior to the measurement.

The probe 105 is brought into contact with the front surface o f the back-incident type photodetector 110 on the device placement portion 111 of the measurement stage 102, and various device characteristics of the back-incident type photodetector 110 receiving the laser light are measured.

In the power supply unit 200, the first electric switch 202 selects the point A1 and the second electric switch 205 selects the point A2, and in the light source unit 300, the optical switch 305 selects the path C, so that basic device characteristics of the back-incident type photodetector 110 are obtained by using CW laser light and the electrical wiring without the variable resistor 203 and the variable-capacitance bypass capacitor 204.

In the power supply unit 200, the first electric switch 202 selects the point B1 and the second electric switch 205 selects the point B2, respectively, and the optical switch 305 selects the path D in the light source unit 300, so that basic device characteristics of the back-incident type photodetector 110 are obtained by using pulsed laser light and electrical wiring with the variable resistor 203 and the variable-capacitance bypass capacitor 204. The device characteristics can be obtained to match the customer's usage conditions by appropriately adjusting the resistance value of the variable resistor 203 and the capacitance of the capacitance-variable bypass capacitor 204.

The defocus amount of the lens portion 126 may be changed according to the customer's usage conditions, and the requested CW light or pulsed light may be made incident on the back-incident type photodetector 110, so that the inspection may be carried out in consideration of the customer's usage conditions such as transient response during light input. In the case of carrying out the light overload test of the back-incident type photodetector 110, the optical switch 305 may select the path C, and the inspection of the back-incident type photodetector 110 may be carried out using the optical wiring which does not pass through the optical attenuator 306.

### Effects of Embodiment 1

As described above, in the above-described photodetector inspection apparatus and the photodetector inspection method according to Embodiment 1, the assembly of the back-incident type photodetector prior to characteristics inspection is unnecessary, thus providing an effect that the inspection of various device characteristics can be carried out by the bare back-incident type photodetector. Therefore, it is possible to select the back-incident type photodetector before incorporating it into the final product, and the measurement is performed by the bare back-incident type photodetector, thus providing an effect of evaluating the device characteristics of the bare device without being affected by the parasitic capacitance of the sub-mount. Furthermore, it is possible to perform the inspection under the same conditions as the final product before incorporating the back-incident type photodetector into the final product. In the photodetector inspection apparatus and the photodetector inspection method according to Embodiment 1, the anti-reflection films are formed on the front surface of the device placement portion and on the front surface of the portion opposed to the device placement portion on the back surface side of the measurement stage, thus providing an effect of preventing more efficiently the generation of return light caused by multiple reflection of the laser light.

### Embodiment 2

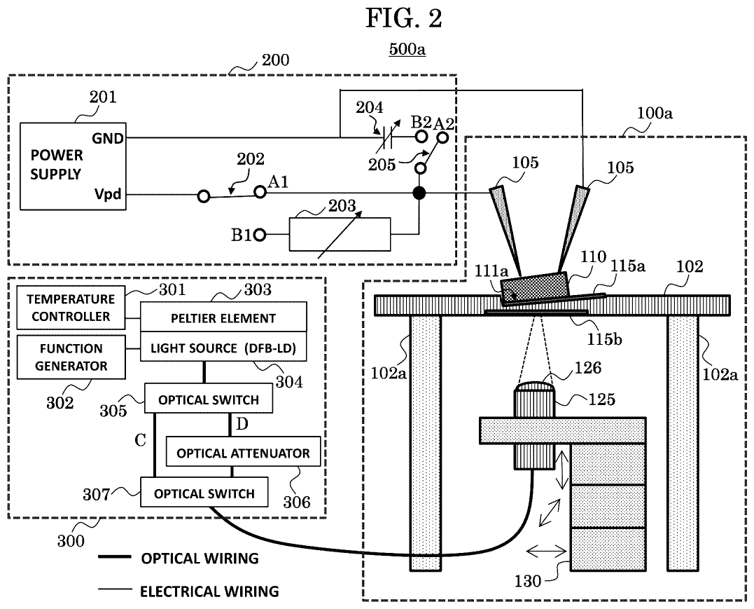

FIG. 2 is an overview diagram showing a photodetector inspection apparatus 500a according to Embodiment 2. The photodetector inspection apparatus 500a includes an inspection unit 100a, a power supply unit 200, and a light source unit 300.

The photodetector inspection apparatus 500a is particularly suitable for measuring the back-incident type photodetector 110, but it is also capable of measuring photodetectors other than the back-incident type photodetector 110.

The power supply unit 200 and the light source unit 300 of the photodetector inspection apparatus 500a according to Embodiment 2 are the same as those of Embodiment 1, but only the inspection unit is different. Therefore, only the inspection unit 100a of the photodetector inspection apparatus 500a according to Embodiment 2 will be described below.

### Structure of Inspection Unit

The inspection unit 100a includes: a measurement stage 102; a plurality of measurement stage legs 102a that support the measurement stage 102; a probe 105 that contacts the back-incident type photodetector 110 to supply a measurement current; an optical fiber unit 125 that is provided on the back surface side of the measurement stage 102 and guides laser light emitted from the light source unit 300 and has a lens portion 126 whose tip is processed into a lens shape; and an XYZ stage 130 that moves the optical fiber unit 125 in a three-dimensional direction.

In the measurement stage 102, at least the region including the device placement portion 111a on which the back-incident type photodetector 110 is placed is formed of a transparent member with respect to the laser light emitted from the light source unit 300. The entire measurement stage 102 may be formed of a transparent member.

The device placement portion 111a of the measurement stage 102 is provided with an inclined surface inclined at a predetermined angle with respect to the front surface of the measurement stage 102. That is, it can be said that the device placement portion 111a provided on the front surface side of the measurement stage 102 has an inclined surface inclined at a predetermined angle with respect to the front surface o f the measurement stage 102. An anti-reflection film 115a is formed on the inclined surface. As shown in FIG. 2, one end of the anti-reflection film 115a is positioned at the same height as the front surface of the measurement stage 102, and the other end of the anti-reflection film 115a is positioned on the inner side from the front surface of the measurement stage 102.

An anti-reflection film 115b is formed on the back surface of the measurement stage 102 opposed to the device placement portion 111a having the inclined surface. The anti-reflection film 115b may be embedded in the transparent member constituting the measurement stage 102 so that the back surface of the measurement stage 102 coincides with the front surface of the anti-reflection film 115b.

In the photodetector inspection apparatus 500a according to Embodiment 2, multiple reflection of the laser light can be prevented when the laser light emitted from the lens portion 126 formed at the tip of the optical fiber unit 125 is focused on the light receiving surface of the back-incident type photodetector 110 placed on the measurement stage 102.

In the photodetector inspection apparatus 500 according to Embodiment 1 described above, although multiple reflection of the laser light by the back surface of the back-incident type photodetector 110 is prevented by the anti-reflection film 115a formed o the device placement portion 111 and the anti-reflection film 115b formed on the back surface of the measurement stage 102 opposed to the device placement portion 111, there is a possibility that the return light due to reflection cannot be completely prevented. Therefore, in the photodetector inspection apparatus 500a according to Embodiment 2, the generation of the return light caused by multiple reflection can be more efficiently prevented by providing the device placement portion 11la having the inclined surface.

### Effects of Embodiment 2

As described above, in the photodetector inspection apparatus according to Embodiment 2, the device placement portion having the inclined surface is provided on the front surface of the measurement stage, thus providing an effect that generation of the return light caused by multiple reflection of the laser light can be more efficiently prevented.

### Embodiment 3

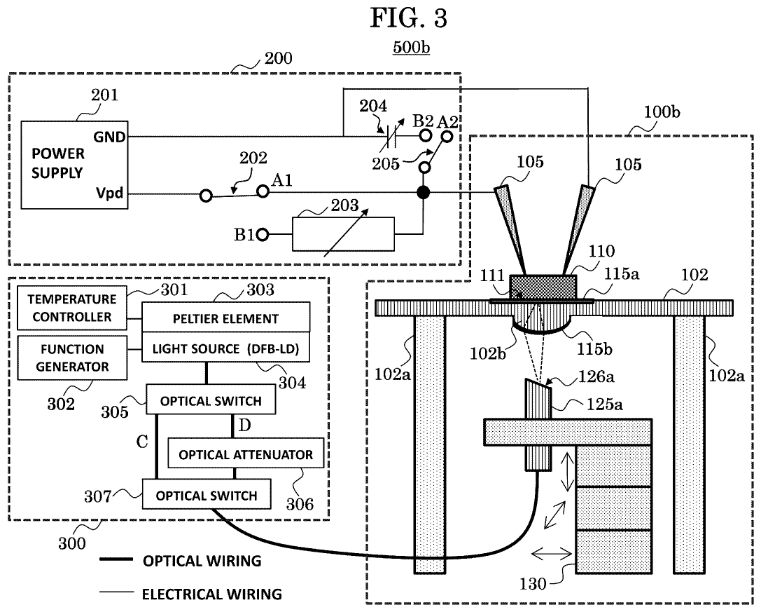

FIG. 3 is an overview diagram showing a photodetector inspection apparatus 500b according to Embodiment 3. The photodetector inspection apparatus 500b includes an inspection unit 100b, a power supply unit 200, and a light source unit 300.

The photodetector inspection apparatus 500b is particularly suitable for measuring the back-incident type photodetector 110, but it is also capable of measuring photodetectors other than the back-incident type photodetector 110.

The power supply unit 200 and the light source unit 300 of the photodetector inspection apparatus 500b according to Embodiment 3 are the same as those of Embodiment 1, but only the inspection unit is different. Therefore, only the inspection unit 100b of the photodetector inspection apparatus 500b according to Embodiment 3 will be described below.

### Structure of Inspection Unit

The inspection unit 100b includes: a measurement stage 102; a plurality of measurement stage legs 102a that support the measurement stage 102; a probe 105 that contacts the back-incident type photodetector 110 to supply a measurement current; an optical fiber unit 125a that is provided on the back surface side of the measurement stage 102 and guides laser light emitted from the light source unit 300 and has an oblique polishing portion 126a whose tip is obliquely polished with respect to the optical axis direction; and an XYZ stage 130 that moves the optical fiber unit 125a in a three-dimensional direction.

In the measurement stage 102, at least the region including the device placement portion 111 on which the back-incident type photodetector 110 is placed is formed of a transparent member with respect to the laser light emitted from the light source unit 300. The entire measurement stage 102 may be formed of a transparent member.

An anti-reflection film 115a is formed on the front surface of the device placement portion 111 of the measurement stage 102. A portion opposed to the device placement portion 111 on the back surface of the measurement stage 102 has a lens spherical portion 102b. An anti-reflection film 115b is formed on the front surface of the lens spherical portion 102b.

In the photodetector inspection apparatus 500b according to Embodiment 3, the laser light emitted from the oblique polishing portion 126a formed at the tip of the optical fiber unit 125 is focused on the light receiving surface of the back-incident type photodetector 110 by using the lens spherical portion 102b formed on the back surface of the measurement stage 102.

In the photodetector inspection apparatus 500b according to Embodiment 3, the anti-reflection film 115a is formed on the front surface of the device placement portion 111 and the anti-reflection film 115b is formed on the front surface of the lens spherical portion 102b opposed to the device placement portion 111 on the back surface side of the measurement stage 102, thereby it is possible to efficiently prevent the generation of return light caused by multiple reflection of the laser light by the back surface of the back-incident type photodetector 110.

### Effects of Embodiment 3

As described above, in the photodetector inspection apparatus according to Embodiment 3, the lens spherical portion is formed on the back surface of the measurement stage, thus providing an effect of enabling the laser light to be efficiently focused, and the anti-reflection film is formed on the front surface side of the measurement stage and the anti-reflection film is formed on the front surface of the lens spherical portion, thus providing an effect of enabling generation of the return light caused by the multiple reflection o f the laser light to be efficiently prevented.

### Embodiment 4

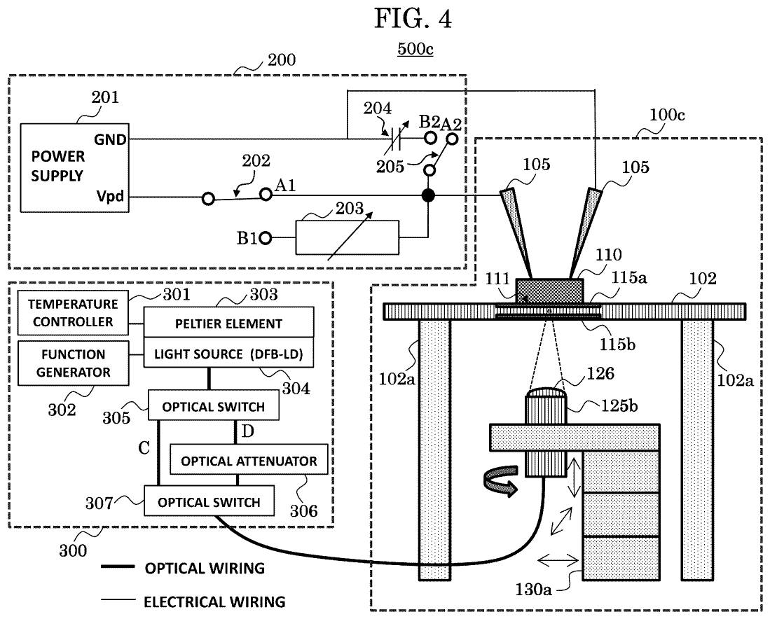

FIG. 4 is an overview diagram showing a photodetector inspection apparatus 500c according to Embodiment 4. The photodetector inspection apparatus 500c includes an inspection unit 100c, a power supply unit 200, and a light source unit 300.

The photodetector inspection apparatus 500c is particularly suitable for measuring the back-incident type photodetector 110, but it is also capable of measuring photodetectors other than the back-incident type photodetector 110.

The power supply unit 200 and the light source unit 300 of the photodetector inspection apparatus 500c according to Embodiment 4 are the same as those of Embodiment 1, except for the inspection unit. Therefore, only the inspection unit 100c of the photodetector inspection apparatus 500c according to Embodiment 4 will be described below.

### Structure of Inspection Unit

The inspection unit 100c includes: a measurement stage 102; a plurality of measurement stage legs 102a that support the measurement stage 102; a probe 105 that contacts the back-incident type photodetector 110 to supply a measurement current; an optical fiber unit 125b that is provided on the back surface side of the measurement stage 102 and guides laser light emitted from the light source unit 300 and has a lens portion 126 whose tip is processed into a lens shape; and an XYZ stage 130a equipped with a rotation mechanism that allows the optical fiber unit 125b to be moved in the three-dimensional direction and rotated around the optical axis direction.

The optical fiber constituting the optical fiber unit 125b is a polarization-maintaining optical fiber. Rotating the optical fiber unit 125b around the optical axis direction by the XYZ stage 130a allows the laser light with a rotated polarization direction to be incident on the light receiving surface of the back-incident type photodetector 110.

The photodetector inspection apparatus 500c according to Embodiment 4 can further measure the polarization dependence of the back-incident type photodetector 110 in addition to the device characteristics that can be measured by the photodetector inspection apparatus 500 according to Embodiment 1.

### Effects of Embodiment 4

As described above, in the photodetector inspection apparatus according to Embodiment 4, the rotation mechanism that rotates the polarization-maintaining type optical fiber around the optical axis direction is provided, thus providing an effect of enabling further measurement of the polarization dependence of a back-incident type photodetector.

### Embodiment 5

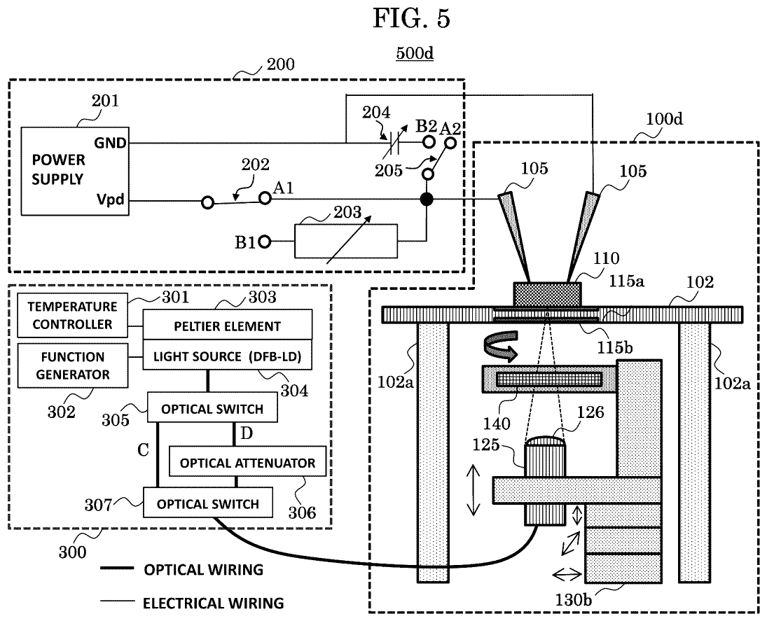

FIG. 5 is an overview diagram showing a photodetector inspection apparatus 500d according to Embodiment 5. The photodetector inspection apparatus 500d includes an inspection unit 100d, a power supply unit 200, and a light source unit 300.

The photodetector inspection apparatus 500d is particularly suitable for measuring the back-incident type photodetector 110, but it is also capable of measuring photodetectors other than the back-incident type photodetector 110.

The power supply unit 200 and the light source unit 300 of the photodetector inspection apparatus 500d according to Embodiment 5 are the same as those of Embodiment 1, except for the inspection unit. Therefore, only the inspection unit 100d of the photodetector inspection apparatus 500d according to Embodiment 5 will be described below.

### Structure of Inspection Unit

The inspection unit 100d includes: a measurement stage 102; a plurality of measurement stage legs 102a that support the measurement stage 102; a probe 105 that contacts the back-incident type photodetector 110 to supply a measurement current; an optical fiber unit 125 that is provided on the back surface side of the measurement stage 102 and guides laser light emitted from the light source unit 300 and has a lens portion 126 whose tip is processed into a lens shape; and an XYZ stage 130b that moves the optical fiber unit 125 in the three-dimensional direction and supports a wavelength plate 140 such that it is positioned between the optical fiber unit 125 and the measurement stage 102 and can rotate around the optical axis direction.

An example of the wavelength plate 140 is a λ/2 plate. Here, λ is the wavelength of the laser light emitted from the light source unit 300.

The wavelength plate 140 is rotated around the optical axis direction using the rotation mechanism provided by the XYZ stage 130b, so that the laser light rotated in the polarization direction is incident on the light receiving surface of the back-incident type photodetector 110.

The photodetector inspection apparatus 500d according to Embodiment 5 can further measure the polarization dependence in addition to the device characteristics of the back-incident type photodetector 110 that can be measured by the photodetector inspection apparatus 500 according to Embodiment 1.

### Effects of Embodiment 5

As described above, in the photodetector inspection apparatus according to Embodiment 5, the wavelength plate capable of rotating around the optical axis direction is arranged between the optical fiber unit and the measurement stage, thus providing an effect of enabling further measurement of the polarization dependence of a back-incident type photodetector.

### Embodiment 6

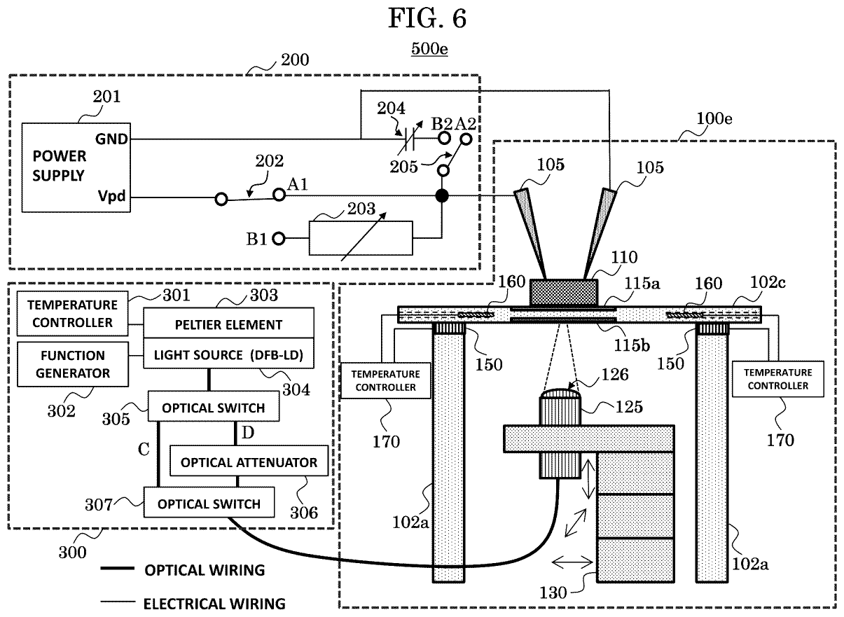

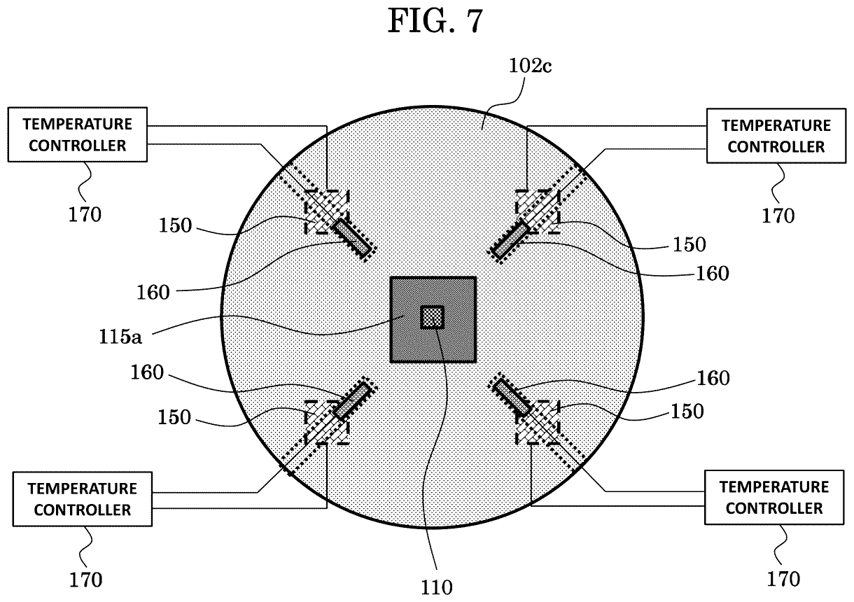

FIG. 6 is an overview diagram showing the photodetector inspection apparatus 500e according to Embodiment 6. FIG. 7 is a top view showing the measurement stage 102c of the photodetector inspection apparatus 500e according to Embodiment 6. The photodetector inspection apparatus 500e includes an inspection unit 100e, a power supply unit 200, and a light source unit 300.

The photodetector inspection apparatus 500e is particularly suitable for measuring the back-incident type photodetector 110, but it is also capable of measuring photodetectors other than the back-incident type photodetector 110.

The power supply unit 200 and the light source unit 300 of the photodetector inspection apparatus 500e according to Embodiment 6 are the same as those of Embodiment 1, but only the inspection unit is different. Therefore, only the inspection unit 100e of the photodetector inspection apparatus 500e according to Embodiment 6 will be described below.

### Structure of Inspection Unit

The inspection unit 100e includes: a measurement stage 102c, a plurality of measurement stage legs 102a that support the measurement stage 102; a plurality of thermistors 160 embedded in the measurement stage 102c; a plurality of Peltier elements 150 provided at portions of the measurement stage legs 102a in contact with the measurement stage 102c, a plurality of temperature controllers 170 respectively connected to the thermistors 160 and the Peltier elements 150; a probe 105 that contacts the back-incident type photodetector 110 to supply a measurement current; an optical fiber unit 125 that is provided on the back surface side of the measurement stage 102 and guides laser light emitted from the light source unit 300 and has a lens portion 126 whose tip is processed into a lens shape; and an XYZ stage 130 that moves the optical fiber unit 125 in a three-dimensional direction.

FIG. 7 is a top view of the measurement stage 102c showing examples of arrangements of four thermistors 160, four Peltier elements 150, and four temperature controllers 170 in the photodetector inspection apparatus 500e according to Embodiment 6.

In the photodetector inspection apparatus 500e according to Embodiment 6, the temperature of the back-incident type photodetector 110 is controlled through the measurement stage 102c using the Peltier elements 150 described above. The temperature controllers 170 control the Peltier elements 150 to control the temperature of the back-incident type photodetector 110 to a desired temperature while referring to the temperature value measured by the thermistors 160 embedded in the measurement stage 102c.

The photodetector inspection apparatus 500e according to Embodiment 6 can further measure the temperature dependence of each device characteristics of the back-incident type photodetector 110 by utilizing the temperature control of the back-incident type photodetector 110 by the Peltier elements 150.

### Effects of Embodiment 6

As described above, in the photodetector inspection apparatus and the photodetector inspection method according to Embodiment 6, the temperature control of the back-incident type photodetector is performed by the Peltier elements, thus providing an effect of enabling further measurement of temperature dependence of each device characteristics of a back-incident type photodetector.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

100, 100a, 100b, 100c, 100d, 100e inspection unit
102, 102c measurement stage
102a measurement stage leg
102b lens spherical portion
105 probe
110 back-incident type photodetector
111, 111a device placement portion
115a anti-reflection film
115b anti-reflection film
125, 125a, 125b optical fiber unit
126 lens portion
130, 130a, 130b XYZ stage
150, 303 Peltier element
160 thermistor
200 power supply unit
201 power supply
202 first electric switch
203 variable resistor
204 Capacitance-variable bypass capacitor
205 second electric switch
300 light source unit
170, 301 temperature controller
302 function generator
304 light source
305, 307 optical switch
306 optical attenuator
500, 500a, 500b, 500c, 500d, 500e photodetector inspection apparatus

1. A photodetector inspection apparatus for inspecting a back-incident type photodetector configured to receive laser light incident from the back surface side comprising:
a measurement stage comprising a region including a device placement portion for placing the back-incident type photodetector with the light receiving surface thereof in contact, the region being formed of a transparent member with respect to the laser light;
anti-reflection films that are configured to prevent reflection of the laser light, the anti-reflection films being formed on the front surface of the device placement portion and on the front surface of a portion opposed to the device placement portion on the back surface side of the measurement stage, respectively;
a light source unit that is configured to emit the laser light onto the light receiving surface provided on the back surface of the back-incident type photodetector and is capable of selecting either CW light or pulsed light from the laser light; and
an optical fiber unit that is connected at one end to the light source unit and is configured to guide the laser light and to emit the laser light from the other end toward the portion opposed to the device placement portion, wherein
the other end of the optical fiber unit is an oblique polished surface inclined at a predetermined with respect to the optical axis direction, and
a portion opposed to the device placement portion on the back surface side of the measurement stage has a lens shape.

2. The photodetector inspection apparatus according to claim 1, further comprising:
a probe for measuring device characteristics of the back-incident type photodetector; and
a power supply unit for supplying a current to the probe.

3. The photodetector inspection apparatus according to claim 1, wherein
the other end of the optical fiber unit has a lens shape.

4. The photodetector inspection apparatus according to claim 1, wherein
the device placement portion on the front surface side of the measurement stage has an inclined surface inclined at a predetermined angle with respect to the front surface of the measurement stage.

5. (canceled)

6. (canceled)

7. The photodetector inspection apparatus according to claim 1, wherein
a wavelength plate is provided between the portion opposed to the device placement portion on the back surface side of the measurement stage and the other end of the optical fiber unit.

8. The photodetector inspection apparatus according to claim 1, wherein
a plurality of temperature control devices are provided in contact with the measurement stage.

9. The photodetector inspection apparatus according to claim 8, wherein each temperature control device is in contact with each of the corners of a rectangle centered on the device placement portion of the measurement stage in a plan view.

10. The photodetector inspection apparatus according to claim 8, wherein
the temperature control device is a Peltier element.

11. A photodetector inspection method for inspecting a back-incident type photodetector that receives laser light incident from the back surface side, the method comprising:
a step of placing the back-incident type photodetector with the light receiving surface thereof in contact, on a device placement portion of a measurement stage formed of a material transparent to the laser light, the device placement portion being provided with anti-reflection films formed on the front surface side and on the back surface side, respectively and being configured to prevent reflection of the laser light;
a step of emitting the laser light emitted from a light source unit through an optical fiber unit toward a portion opposed to the device placement portion on the back surface side of the measurement stage; and
a step of measuring device characteristics of the back-incident type photodetector by contacting a probe with the front surface of the back-incident type photodetector, wherein
the optical fiber unit comprising a polarization-maintaining optical fiber is rotated around the optical axis direction to emit the laser light with the polarization direction rotated, and polarization dependence of the device characteristics of the back-incident type photodetector is measured.

12. (canceled)

13. (canceled)

14. (canceled)

15. A photodetector inspection apparatus for inspecting a back-incident type photodetector configured to receive laser light incident from the back surface side comprising:
a measurement stage comprising a region including a device placement portion for placing the back-incident type photodetector with the light receiving surface thereof in contact, the region being formed of a transparent member with respect to the laser light;
anti-reflection films that are configured to prevent reflection of the laser light, the anti-reflection films are formed on the front surface of the device placement portion and on the front surface of a portion opposed to the device placement portion on the back surface side of the measurement stage, respectively;
a light source unit that is configured to emit the laser light onto the light receiving surface provided on the back surface of the back-incident type photodetector and is capable of selecting either CW light or pulsed light from the laser light; and
an optical fiber unit that is connected at one end to the light source unit and is configured to guide the laser light and to emit the laser light from the other end toward the portion opposed to the device placement portion; and
a rotating mechanism for rotating the optical fiber unit comprising a polarization-maintaining type optical fiber around the optical axis direction.

16. A photodetector inspection method for inspecting a back-incident type photodetector that receives laser light incident from the back surface side, the method comprising:
a step of placing the back-incident type photodetector with the light receiving surface thereof in contact, on a device placement portion of a measurement stage formed of a material transparent to the laser light, the device placement portion being provided with anti-reflection films formed on the front surface side and on the back surface side, respectively and being configured to prevent reflection of the laser light;
a step of emitting the laser light emitted from a light source unit through an optical fiber unit toward a portion opposed to the device placement portion on the back surface side of the measurement stage; and
a step of measuring device characteristics of the back-incident type photodetector by contacting a probe with the front surface of the back-incident type photodetector, wherein
polarization dependence of the device characteristics of the back-incident type photodetector is measured by rotating a wavelength plate provided between a portion opposed to the device placement portion on the back surface side of the measurement stage and the other end of the optical fiber unit.

17. A photodetector inspection method for inspecting a back-incident type photodetector that receives laser light incident from the back surface side, the method comprising:
a step of placing the back-incident type photodetector with the light receiving surface thereof in contact, on a device placement portion of a measurement stage formed of a material transparent to the laser light, the device placement portion being provided with anti-reflection films formed on the front surface side and on the back surface side, respectively and being configured to prevent reflection of the laser light;
a step of emitting the laser light emitted from a light source unit through an optical fiber unit toward a portion opposed to the device placement portion on the back surface side of the measurement stage; and
a step of measuring device characteristics of the back-incident type photodetector by contacting a probe with the surface side of the back-incident type photodetector, wherein
temperature dependence of the device characteristics of the back-incident type photodetector is measured by controlling the temperature of the back-incident type photodetector mounted on the device placement portion using a temperature control device provided on the measurement stage.
